(19) United States
(12) Patent Application Publication
(10) Pub. No.: US 2026/0095136 A1
(43) Pub. Date: Apr. 2, 2026

(54) BUZZER DEVICE, BUZZER DRIVING SYSTEM AND METHOD THEREOF

(71) Applicant: NUVOTON TECHNOLOGY CORPORATION, HSINCHU CITY (TW)

(72) Inventor: Pao-Shu Chang, zhubei City (TW)

(21) Appl. No.: 19/335,717

(22) Filed: Sep. 22, 2025

Related U.S. Application Data
(60) Provisional application No. 63/701,378, filed on Sep. 30, 2024.

(30) Foreign Application Priority Data
Feb. 3, 2025 (TW) 114103867

(51) Int. Cl. H03G 3/00; H03G 3/30

(52) U.S. Cl. CPC H03G 3/001; H03G 3/004; H03G 3/3005; H03G 2201/702

(57) ABSTRACT

A buzzer driving system includes a filter circuit and a driving circuit. The filter circuit is configured to filter an audio playback signal and output an analog playback signal. The driving circuit is electrically connected to the filter circuit and configured to output a driving voltage to the buzzer based on the analog playback signal. The driving system generates the driving voltage in an analog form to enhance the output audio quality of the buzzer.

### CROSS-REFFERENCE TO RELATED APPLICATION

This application claims priority to U.S. Provisional Patent Application No. 63/701,378, filed on Sep. 30, 2024, and Taiwanese Patent Application No. 114103867, filed on Feb. 3, 2025. The entire contents of both applications are incorporated herein by reference.

### BACKGROUND

### 1. Field of the Invention

The present invention relates to a buzzer device, a driving system for driving a buzzer, and a driving method thereof, and more particularly to a buzzer device, a driving system, and a driving method configured to drive a buzzer by using an analog-form signal.

### 2. Description of the Related Art

Buzzers are sound-generating components that are widely used in products such as alarms, multimedia devices, automotive electronic equipment, and toys. Buzzers are generally categorized into piezoelectric type and electromagnetic type. When the buzzer is powered, a metal diaphragm inside the buzzer vibrates within a resonance chamber to produce sound.

Conventional buzzers are primarily driven by digital signals. As a result, most buzzers can only produce a single tone, and audio details are often filtered out by the buzzer, leading to poor output sound quality that is difficult to compare with that of speakers. Nevertheless, compared to speakers, buzzers still possess irreplaceable advantages such as compact size, high volume output, low cost, and durability. Accordingly, how to overcome the limitations of existing buzzers has become an important issue for those skilled in the art.

### SUMMARY

In view of the foregoing, an aspect of the present invention provides a buzzer device, a buzzer driving system, and a driving method thereof that can drive a buzzer using an analog signal to enhance the sound quality of the buzzer and enable the buzzer to reproduce audio details contained in the audio signal.

To achieve the foregoing aspect, a buzzer driving system according to the present invention comprises a filter circuit and a driving circuit. The filter circuit is configured to receive an audio playback signal, filter the audio playback signal, and output an analog playback signal. The driving circuit is electrically connected to the filter circuit and is configured to output a driving voltage to the buzzer based on the analog playback signal.

Based on an aspect of the present invention, a buzzer device is further provided. The buzzer device comprises a buzzer, a signal processing circuit, a filter circuit, and a driving circuit. The signal processing circuit is configured to perform band-pass filtering on an audio signal according to a first frequency band to generate an audio playback signal. The filter circuit is electrically connected to the signal processing circuit and is configured to filter the audio playback signal and output an analog playback signal. The driving circuit is electrically connected to the filter circuit and is configured to output a driving voltage to the buzzer based on the analog playback signal. The driving circuit operates at an operating voltage that is higher than an operating voltage of the filter circuit.

Based on an aspect of the present invention, a method for driving a buzzer is further provided. The method comprises: receiving an audio signal; performing band-pass filtering on the audio signal according to a first frequency band to generate an audio playback signal; filtering the audio playback signal to output an analog playback signal; generating a single-ended signal based on the analog playback signal; generating a first voltage and a second voltage based on the single-ended signal; and generating a driving voltage to the buzzer based on a voltage difference between the first voltage and the second voltage.

Compared to conventional technologies that drive buzzers using pulse-width modulation (PWM) signals, the buzzer device, the driving system for the buzzer, and the driving method according to the present invention generate the driving voltage required by the buzzer using analog signals. As a result, the buzzer is no longer limited to responding only to digital signals and producing a single tone but is instead capable of delivering speaker-like sound quality and reproducing audio details through analog signal driving. In addition, the filter circuit filters out noise from the original audio signal, thereby ensuring the quality of the audio output generated by the buzzer.

### BRIEF DESCRIPTION OF THE DRAWINGS

FIG. 1 is a block diagram illustrating a buzzer driving system according to an embodiment of the present invention.

FIG. 2 is another block diagram illustrating another buzzer driving system according to another embodiment of the present invention.

FIG. 3 is a block diagram illustrating a buzzer device according to an embodiment of the present invention.

FIG. 4 is a flowchart illustrating a method for driving a buzzer according to an embodiment of the present invention.

### DETAILED DESCRIPTION

An aspect of the present invention is to provide a driving system and method capable of driving a buzzer 2 using an analog-form signal, such that the operation of the buzzer 2 is not limited by whether the input signal is analog or digital. In addition, the buzzer 2 can benefit from the characteristics of analog signals, allowing the sound output from the buzzer 2 to include more audio details rather than being limited to a single tone.

The following provides a detailed description of possible embodiments of the present invention with reference to the drawings. However, it should be noted that the following implementation details are not intended to limit the scope of the claimed invention, but are provided merely to facilitate understanding by those skilled in the art.

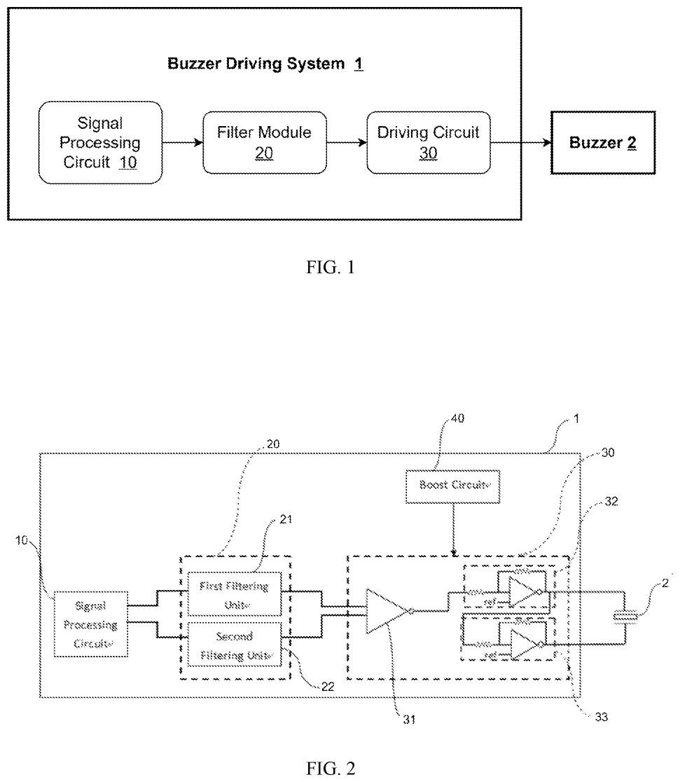

Referring to FIG. 1, a buzzer driving system 1 is electrically connected to a buzzer 2, and comprises a signal processing circuit 10, a filter circuit 20, and a driving circuit 30, according to an embodiment of the present invention. The buzzer driving system 1 is implemented as a system independent from the buzzer 2 and is arranged separately from the buzzer 2. Therefore, the buzzer driving system 1 can be directly applied to an existing buzzer 2 without requiring any modification to the structure of the buzzer 2.

The signal processing circuit 10 receives an audio signal corresponding to the buzzer 2 and performs signal processing on the audio signal. The audio signal may be a digital audio signal or an analog audio signal from an external device, according to an embodiment of the present invention. In an embodiment, the audio signal can include a human voice audio signal, a speech audio signal, or a music audio signal. In an embodiment, the analog audio signal can include an audio signal generated by performing audio signal processing in specific frequency bands on a human voice audio signal, a speech audio signal, or a music audio signal, wherein the aforementioned audio signal processing can include attenuating or enhancing the intensity of the audio signal in specific frequency bands. In one embodiment, the analog audio signal can include an audio signal generated by performing low-pass filtering on a digital signal (for example, a PWM signal). The above descriptions are merely exemplary and do not limit the scope of protection of the present invention.

In one aspect, the signal processing circuit 10 performs band-pass filtering on the audio signal according to a first frequency band to generate an audio playback signal, such that components of the audio signal outside the first frequency band are filtered out. The first frequency band corresponds to the audible frequency range of the human ear, for example, from 20 Hz to 20,000 Hz. The signal processing circuit 10 filters the audio signal using the first frequency band to remove audio components that are inaudible to the human ear.

In another aspect, the signal processing circuit 10 performs gain enhancement on the frequency domain of the audio signal according to a second frequency band to generate the audio playback signal. The signal processing circuit 10 adjusts components of the audio signal within the second frequency band to increase the gain and signal strength of those components. The second frequency band corresponds to a frequency range in which the buzzer 2 exhibits relatively weak frequency response, such as a range in which the frequency response is lower than a predetermined response threshold. The predetermined response threshold may be adjusted according to the type of the buzzer 2 and specific application requirements.

In a preferred embodiment, the signal processing circuit 10 may perform at least one of the following types of signal processing on the audio signal to generate the audio playback signal: performing band-pass filtering using the first frequency band, performing gain enhancement on the frequency domain according to the second frequency band, and removing a component (or a portion) of the audio signal having a gain lower than the predetermined gain. When the signal processing circuit 10 performs more than one type of signal processing on the audio signal, the present invention does not limit the execution order of these processing methods, and the order of different signal processing steps may be interchanged.

For example, the signal processing circuit 10 may first perform band-pass filtering on the audio signal using the first frequency band and then perform gain enhancement on the frequency domain of the filtered audio signal according to the second frequency band to generate the audio playback signal. Alternatively, the signal processing circuit 10 can first remove a component (or a portion) of the audio signal having a gain lower than the predetermined gain, then perform gain enhancement on the frequency domain of the audio signal according to the second frequency band, and finally perform band-pass filtering on the audio signal using the first frequency band to generate the audio playback signal. It should be noted that the above descriptions are provided for illustrative purposes only and are not intended to limit the implementation of the signal processing circuit 10. The sequence of signal processing steps for the audio signal is not limited to the specific embodiments described herein.

The filter circuit 20 is electrically connected to the signal processing circuit 10 to receive the audio playback signal and filters the audio playback signal to generate an analog playback signal. While filtering the signal, the filter circuit 20 converts the audio playback signal into a corresponding analog signal. The filter circuit 20 may include a low-pass filter. The audio playback signal may be a pulse-width modulation (PWM) signal or an analog signal.

The driving circuit 30 is electrically connected to the filter circuit 20 to receive the analog playback signal and generates a driving voltage to the buzzer 2 based on the analog playback signal.

Referring to FIG. 2, in this embodiment, the audio playback signal is an audio differential signal generated by the signal processing circuit 10 through processing the audio signal. The filter circuit 20 includes a first filter unit 21 and a second filter unit 22. The first filter unit 21 receives the positive component of the audio differential signal, and the second filter unit 22 receives the negative component of the audio differential signal. The filter circuit 20 filters the audio differential signal through the first filter unit 21 and the second filter unit 22 to generate the analog playback signal. The first filter unit 21 and the second filter unit 22 may each be implemented as a low-pass filter. The analog playback signal may be an analog differential signal.

In the embodiment shown in FIG. 2, the driving circuit 30 includes a differential amplifier 31, a first-stage amplifier 32, and a second-stage amplifier 33. The differential amplifier 31 has a pair of differential input terminals and an output terminal. The pair of differential input terminals is electrically connected to the first filter unit 21 and the second filter unit 22 to receive the analog differential signal. The differential amplifier 31 amplifies the analog differential signal and generates a single-ended signal, which is output through the output terminal. In addition to amplifying the voltage of the analog differential signal, the differential amplifier 31 also suppresses common-mode noise within the analog differential signal to enhance the quality of the single-ended signal.

The first-stage amplifier 32 includes a first input terminal, a second input terminal, and an output terminal. The first input terminal of the first-stage amplifier 32 is electrically connected to the output terminal of the differential amplifier 31 to receive the single-ended signal. The second input terminal of the first-stage amplifier 32 is electrically connected to a voltage reference. The output terminal of the first-stage amplifier 32 is electrically connected to a positive terminal of the buzzer 2. The first-stage amplifier 32 amplifies the single-ended signal and outputs a first voltage through the output terminal of the first-stage amplifier 32.

The second-stage amplifier 33 includes a first input terminal, a second input terminal, and an output terminal. The first input terminal of the second-stage amplifier 33 is electrically connected to the output terminal of the first-stage amplifier 32 to receive the first voltage. The second input terminal of the second-stage amplifier 33 is electrically connected to the reference voltage (ref). The output terminal of the second-stage amplifier 33 is electrically connected to a negative terminal of the buzzer 2. The second-stage amplifier 33 amplifies the first voltage and outputs a second voltage through the output terminal of the second-stage amplifier 33.

The driving voltage corresponds to a difference between the first voltage and the second voltage. The driving circuit 30 outputs the driving voltage to the buzzer 2 through the first-stage amplifier 32 and the second-stage amplifier 33 to drive the buzzer 2 to generate a sound corresponding to the driving voltage.

In the embodiment shown in FIG. 2, the buzzer driving system 1 may further comprise a voltage booster circuit 40. The voltage booster circuit 40 is electrically connected to an external power source and the driving circuit 30. The voltage booster circuit 40 outputs a working voltage to the driving circuit 30 based on an external voltage supplied by the external power source to increase the operating voltage of the driving circuit 30, such that the operating voltage of the driving circuit 30 is higher than that of the filter circuit 20.

Referring to FIG. 3, a buzzer device 100 is also provided according to an embodiment of the present invention. The buzzer device 100 differs from the buzzer driving system 1 in that the buzzer device 100 integrates the signal processing circuit 10, the filter circuit 20, and the driving circuit 30 of the buzzer driving system 1 with the buzzer 2. Thus, the buzzer device 100 comprises the signal processing circuit 10, the filter circuit 20, the driving circuit 30, and the buzzer 2. Compared to the buzzer driving system 1, which is intended to be applied to an existing buzzer 2, the buzzer device 100 provides users with another option of the buzzer 2 to meet different usage requirements.

The buzzer 2 may be a piezoelectric buzzer 2, which mainly comprises a piezoelectric element, a metal plate, and a housing. The piezoelectric element may be formed of a piezoelectric ceramic material. When subjected to an applied voltage, the piezoelectric element deforms due to the piezoelectric effect and drives the metal plate to vibrate, thereby generating sound. The housing not only encases the piezoelectric element and the metal plate but also forms a resonant chamber for the piezoelectric element and the metal plate.

Compared to conventional speakers, the buzzer 2 has advantages such as lower power consumption, louder sound output, smaller size, lower cost, and greater durability. In addition, due to its structural and material characteristics, the buzzer 2 exhibits higher durability and stability even under extreme conditions such as high temperature or humidity. Unlike speakers, which are prone to damage and are relatively expensive, the buzzer 2 offers irreplaceable advantages.

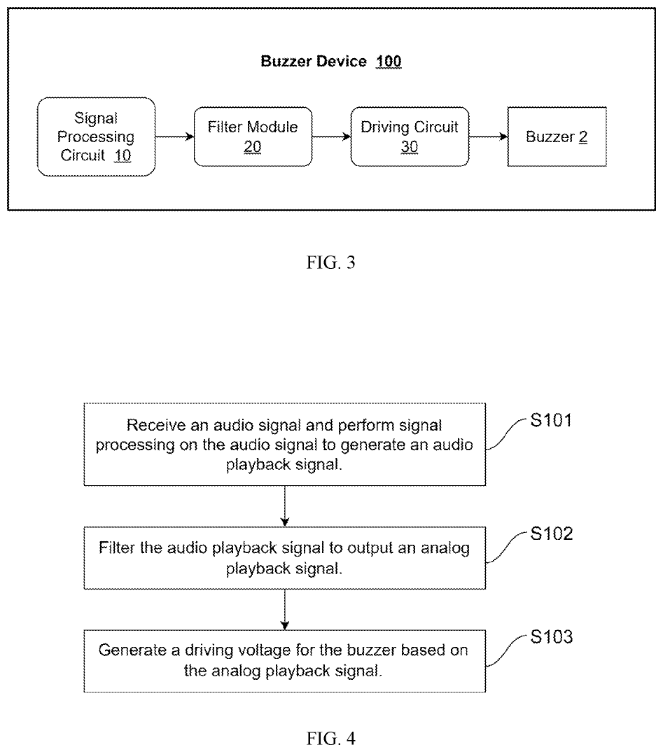

Referring to FIG. 4, a buzzer driving method according to the present invention is applied to the buzzer 2, and may be executed by the buzzer driving system 1 or the buzzer device 100. The method comprises the following steps.

S101: An audio signal is received and subjected to signal processing to generate an audio playback signal. The step S101 may be performed by the signal processing circuit 10. The signal processing of the audio signal can include performing band-pass filtering based on a first frequency band, gain enhancement in the frequency domain based on a second frequency band, or removing a portion of the audio signal having a gain lower than a predetermined gain in the frequency domain.

S102: The audio playback signal is filtered to output an analog playback signal. The step S102 may be performed by the filter circuit 20.

S103: A driving voltage is output to the buzzer 2 based on the analog playback signal. The step S103 can be performed by the driving circuit 30. In the step S103, the analog playback signal is first amplified to generate a single-ended signal, and then a first voltage and a second voltage are generated based on the single-ended signal. The driving voltage corresponds to a voltage difference between the first voltage and the second voltage.

In summary, the buzzer device 100, the buzzer driving system 1, and the associated method of the present invention are capable of processing analog signals to generate the driving voltage required by the buzzer 2. Compared to conventional methods that operate the buzzer 2 using pulse-width modulation (PWM) signals, the present invention enables the buzzer 2 to operate without being limited to digital signals and producing only a single tone. Instead, by utilizing analog signals, the sound details of the original audio can be preserved, allowing the buzzer 2 to deliver sound quality comparable to that of a regular speaker, while retaining the advantages of loud output volume, low component cost, and high durability.

In addition, the signal processing circuit 10 of the present invention can also perform signal processing based on the frequency response of the corresponding buzzer 2, so that the original audio, after processing, better matches the operational characteristics of the buzzer 2. Moreover, the signal processing circuit 10 and the filter circuit 20 can filter out noise from the original audio to further enhance the sound quality output by the corresponding buzzer 2.

The present invention is disclosed through embodiments in this specification. However, any person skilled in the art will understand that the embodiments are provided for illustrative purposes only and do not limit the scope of the claimed invention. Any equivalent or modified variations shall be interpreted as comprised within the spirit and scope of the present invention. Therefore, the scope of protection of the present invention shall be defined by the appended claims.

What is claimed is:

1. A buzzer driving system, comprising,
a filter circuit configured to receive an audio playback signal, filter the audio playback signal, and output an analog playback signal; and
a driving circuit electrically connected to the filter circuit and configured to output a driving voltage to the buzzer based on the analog playback signal.

2. The buzzer driving system according to claim 1, wherein the filter circuit comprises a low-pass filter.

3. The buzzer driving system according to claim 1, wherein the audio playback signal is a pulse-width modulation (PWM) signal or an analog signal.

4. The buzzer driving system according to claim 1,
wherein the audio playback signal is an audio differential signal,
the filter circuit comprises a first filter unit and a second filter unit, and
the driving circuit comprises:
a differential amplifier comprising a pair of differential input terminals configured to receive the analog playback signal and an output terminal configured to output a single-ended signal;
a first-stage amplifier electrically connected to the output terminal of the differential amplifier and configured to output a first voltage at an output terminal of the first-stage amplifier based on the single-ended signal, wherein the output terminal of the first-stage amplifier is electrically connected to a positive terminal of the buzzer; and
a second-stage amplifier electrically connected to the output terminal of the first-stage amplifier and configured to output a second voltage at an output terminal of the second-stage amplifier based on the first voltage, wherein the output terminal of the second-stage amplifier is electrically connected to a negative terminal of the buzzer,
wherein the driving voltage corresponds to a voltage difference between the first voltage and the second voltage.

5. The buzzer driving system according to claim 1, further comprising a signal processing circuit electrically connected to the filter circuit and configured to receive an audio signal, wherein the signal processing circuit is configured to perform band-pass filtering on the audio signal according to a first frequency band to generate the audio playback signal.

6. The buzzer driving system according to claim 5, wherein the signal processing circuit is configured to perform gain enhancement on a frequency domain of the audio signal according to a second frequency band to generate the audio playback signal.

7. The buzzer driving system according to claim 5, wherein the signal processing circuit is configured to remove a portion of the audio signal to generate the audio playback signal, wherein the portion of the audio signal has a gain lower than a predetermined gain in the frequency domain.

8. The buzzer driving system according to claim 1, wherein an operating voltage of the driving circuit is higher than an operating voltage of the filter circuit.

9. A buzzer device, comprising,
a buzzer;
a signal processing circuit configured to perform band-pass filtering on an audio signal according to a first frequency band to generate an audio playback signal;
a filter circuit electrically connected to the signal processing circuit and configured to filter the audio playback signal and output an analog playback signal; and
a driving circuit electrically connected to the filter circuit and configured to output a driving voltage to the buzzer based on the analog playback signal,
wherein an operating voltage of the driving circuit is higher than an operating voltage of the filter circuit.

10. A driving method for a buzzer, comprising:
receiving an audio signal;
performing band-pass filtering on the audio signal based on a first frequency band to generate an audio playback signal;
filtering the audio playback signal to output an analog playback signal;
generating a single-ended signal based on the analog playback signal;
generating a first voltage and a second voltage based on the single-ended signal; and
generating a driving voltage to the buzzer based on a voltage difference between the first voltage and the second voltage.
